(19) United States
(12) Patent Application Publication
(10) Pub. No.: US 2019/0027430 A1
(43) Pub. Date: Jan. 24, 2019

(54) SEMICONDUCTOR PACKAGE WITH NICKEL PLATING AND METHOD OF FABRICATION THEREOF

(71) Applicant: Infineon Technologies AG, Neubiberg (DE)

(72) Inventor: Soon Lock Goh, Malacca (MY)

(73) Assignee: Infineon Technologies AG, Neubiberg (DE)

(21) Appl. No.: 16/036,127

(22) Filed: Jul. 16, 2018

(30) Foreign Application Priority Data
Jul. 20, 2017 (DE) 10 2017 212 457.1

(51) Int. Cl. H01L 23/495; H01L 23/31; H01L 21/48; H01L 21/56; H01L 21/02

(52) U.S. Cl. CPC H01L 23/49582; H01L 23/3121; H01L 21/02521; H01L 21/56; H01L 21/4821

(57) ABSTRACT

A semiconductor package and method for fabricating a semiconductor package is disclosed. In one aspect, the method includes providing a substrate, at least partially encapsulating the substrate in an encapsulation body, and depositing by electroplating a first Ni layer on a first surface of the substrate. A second Ni layer by electroless Ni plating is deposited on the first Ni layer.

### CROSS-REFERENCE TO RELATED APPLICATION

This Utility patent application claims priority to German Patent Application No. 10 2017 212 457.1, filed Jul. 20, 2017, which is incorporated herein by reference.

### TECHNICAL FIELD

This disclosure relates in general to a semiconductor package comprising a Ni plating and to a method for fabricating such a semiconductor package.

### BACKGROUND

Semiconductor packages may comprise outer contacts that are covered by one or more metal layers. Such metal layers may e.g. be used to improve the electrical characteristics of the semiconductor package, to be able to connect the outer contacts to pads on a customer board, or to improve the durability of the outer contacts. Ni is an example for such a metal that is used to cover outer contacts. Fabrication of such metal layers may comprise several steps, may require expensive machinery, may comprise the use of costly catalysts and may be time consuming. Improved fabrication methods may help to overcome these problems and may also yield semiconductor packages with improved electrical and/or mechanical characteristics.

For these and other reasons, there is a need for improved semiconductor packages and for improved methods of fabricating semiconductor packages.

### SUMMARY

Various aspects pertain to a method for fabricating a semiconductor package, wherein the method comprises providing a substrate, at least partially encapsulating the substrate in an encapsulation body, depositing by electroplating a first Ni layer on a first surface of the substrate and depositing by electroless Ni plating a second Ni layer on the first Ni layer.

Various aspects pertain to a method for fabricating a semiconductor package, wherein the method comprises providing a substrate, wherein the substrate comprises on a first surface a first Ni layer, at least partially encapsulating the substrate and the first Ni layer in an encapsulation body and depositing by electroless Ni plating a second Ni layer on the first Ni layer.

Various aspects pertain to a semiconductor package, wherein the semiconductor package comprises an encapsulation body, a substrate, the substrate being exposed from the encapsulation body on a first main face and at least one side face of the encapsulation body, a first Ni layer arranged on the substrate at the first main face of the encapsulation body and a second Ni layer arranged on the first Ni layer and on the substrate at the at least one side face of the encapsulation body.

### BRIEF DESCRIPTION OF THE DRAWINGS

The accompanying drawings illustrate examples and together with the description serve to explain principles of the disclosure. Other examples and many of the intended advantages of the disclosure will be readily appreciated as they become better understood by reference to the following detailed description. The elements of the drawings are not necessarily to scale relative to each other. Like reference numerals designate corresponding similar parts.

FIG. 1A shows a side view of an exemplary semiconductor package comprising outer contacts on a first main face.

FIG. 1B shows a side view of the semiconductor package of FIG. 1A, wherein metal layers are arranged on the outer contacts.

FIGS. 2A to 2h show side views of a semiconductor package in various stages of production according to an exemplary method of fabrication.

FIG. 3 shows a side view of a further exemplary semiconductor package.

FIGS. 4A to 4D show side views of a semiconductor package in various stages of production according to another exemplary method of fabrication.

FIG. 5 shows a perspective view of a semiconductor package comprising outer contacts, wherein the outer contacts are exposed on a first main face and on side faces of the semiconductor package.

FIG. 6 shows a flow chart of an exemplary method for fabricating a semiconductor package.

FIG. 7 shows a flow chart of another exemplary method for fabricating a semiconductor package.

### DETAILED DESCRIPTION

In the following detailed description, reference is made to the accompanying drawings. It may be evident, however, to one skilled in the art that one or more aspects of the disclosure may be practiced with a lesser degree of the specific details. In other instances, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration and is in no way limiting. It is to be understood that other examples may be utilized and structural or logical changes may be made without departing from the scope of the present invention. The following detailed description, therefore, is not to be taken in a limiting sense, and the scope of the present invention is defined by the appended claims.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements co-operate or interact with each other regardless whether they are in direct physical or electrical contact, or they are not in direct contact with each other; intervening elements or layers may be provided between the “bonded”, “attached”, or “connected” elements. Also, the term “exemplary” is merely meant as an example, rather than the best or optimal. The following detailed description, therefore, is not to be taken in a limiting sense, and the scope of the present invention is defined by the appended claims.

The semiconductor chip(s) described further below may be of different types, may be manufactured by different technologies and may include for example integrated electrical, electro-optical or electro-mechanical circuits and/or passives, logic integrated circuits, control circuits, microprocessors, memory devices, etc.

The semiconductor packages described below may include one or more semiconductor chips. By way of example, one or more semiconductor power chips may be included. Further, one or more logic integrated circuits may be included in the devices. The logic integrated circuits may be configured to control the integrated circuits of other semiconductor chips, for example the integrated circuits of power semiconductor chips. The logic integrated circuits may be implemented in logic chips.

The semiconductor chip(s) may be bonded to a carrier. The carrier may be a (permanent) device carrier used for packaging. The carrier may comprise or consist of any sort of material as, for example, metallic material, copper or copper alloy or iron/nickel alloy. The carrier can be connected mechanically and electrically with one or more contact elements of the semiconductor chip(s).

The semiconductor chip(s) may be covered with an encapsulation material in order to be embedded in an encapsulant (artificial wafer). The encapsulation material may be electrically insulating. The encapsulation material may comprise or be made of any appropriate plastic or polymer material such as, e.g., a duroplastic, thermoplastic or thermosetting material or laminate (prepreg), and may e.g. contain filler materials. Various techniques may be employed to encapsulate the semiconductor chip(s) with the encapsulation material, for example compression molding, injection molding, powder molding, liquid molding or lamination. Heat and/or pressure may be used to apply the encapsulation material.

In several examples layers or layer stacks are applied to one another or materials are applied or deposited onto layers. It should be appreciated that any such terms as “applied” or “deposited” are meant to cover literally all kinds and techniques of applying layers onto each other. In particular, they are meant to cover techniques in which layers are applied at once as a whole like, for example, laminating techniques as well as techniques in which layers are deposited in a sequential manner like, for example, sputtering, plating, molding, CVD, etc.

The semiconductor packages described below may be different types of packages and may for example be leadless semiconductor packages. A “leadless” semiconductor package may be a package, wherein outer contacts do not “stick out” of an encapsulation body of the package. Examples of such leadless packages are QFN (quad-flat no-leads), DFN (dual-flat no-leads) and TSNP (thin small non-leaded package). The semiconductor packages described below may be configured to be mounted to a customer board by surface mount technology (SMT). The semiconductor packages described below may comprise outer contacts that are exposed on a first main face of the semiconductor package and on at least one side face of the package. In particular, an exposed part of the outer contact one the first main face and on the at least one side face may be one contiguous exposed surface of the outer contact.

The semiconductor packages described below may comprise a substrate. The substrate may comprise the carrier and one or more outer contacts of the semiconductor package. The substrate may comprise a leadframe, wherein the carrier and the one or more outer contacts are parts of the leadframe. The substrate may comprise or consist of a metal or metal alloy like, e.g., Cu or Fe.

The semiconductor packages described below may comprise a first Ni layer arranged on the outer contact(s), in particular on an exposed surface of the outer contacts. The first Ni layer may be deposited on the outer contact(s). For example, a Ni electroplating process may be used to deposit the first Ni layer. Ni electroplating may comprise immersing the semiconductor package into an electrolyte solution and using the outer contact(s) as a cathode. According to an example, the semiconductor package is still part of an artificial wafer during the Ni electroplating process. In other words, the artificial wafer is immersed into the electrolyte solution as a whole. According to an example, the first Ni layer forms solely on the first main face of the semiconductor package, but not on the side faces.

According to an example, the semiconductor packages described below do not comprise a first Ni layer but a first metal layer comprising another metal like, e.g., Pd, that may act as a catalyst for the electroless Ni plating of the second Ni layer. For example, the first metal layer may be a first Pd layer.

According to an example, the first Ni layer is free of any phosphorus or boron. The first Ni layer may be a pure Ni layer except for small quantities of inevitable impurities stemming from the fabrication process.

The semiconductor packages described below may comprise a second Ni layer arranged on the first Ni layer. For example, an electroless Ni plating process may be used to deposit the second Ni layer on the first Ni layer. Electroless Ni plating is an autocatalytic reaction that does not require an electric current. Electroless Ni plating may comprise adding an additive like phosphorus (P) to the Ni. For example, the second Ni layer may comprise P at an amount of less than, about, or more than 5%, 8%, 10%, or 12% of the second Ni layer.

The second Ni layer may be deposited directly on top of the first Ni layer. Because the first Ni layer may act as a “seed layer” it may not be necessary to pre-treat the semiconductor package with, e.g., Pd prior to the electroless Ni plating process. In particular, it may not be necessary to provide a Pd layer onto which the second Ni layer can be deposited by electroless Ni plating. Therefore, the semiconductor packages described below may be free of any Pd layers. In particular, the semiconductor packages described below may be free of any Pd between the first Ni layer and the second Ni layer.

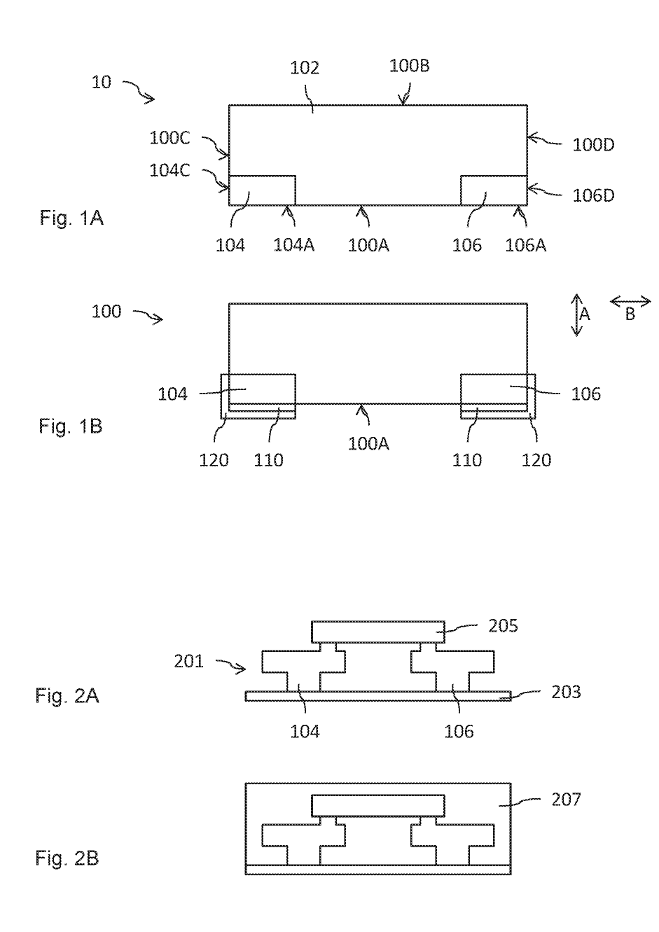

FIG. 1A shows a semiconductor package 10 comprising an encapsulation body 102 and outer contacts 104, 106. The semiconductor package 10 further comprises one or more semiconductor chips which are not shown in FIG. 1A. The semiconductor chip(s) may be mechanically and/or electrically coupled to the outer contacts 104, 106. For example, the outer contacts 104, 106 may be parts of a leadframe and may be outer contacts and chip carriers at the same time.

First outer contact surfaces 104A, 106A of the outer contacts 104, 106 may be exposed from the encapsulation body 102 at a first main face 100A of the semiconductor package 10 and outer contact side faces 104C, 106D may be exposed from the encapsulation body 102 at respective side faces 100C, 100D of the semiconductor package 10. Because of the exposed outer contact side faces 104C, 106D, the outer contacts 104, 106 may be termed side assist pads (SAPs). A second main face 100B of the semiconductor package 10 may be free of any outer contacts. The respective outer contact surfaces and side faces 104A, 104C and 106A, 106D may each form a contiguous outer contact surface of the respective outer contacts 104 and 106.

As shown in FIG. 1A, the encapsulation body 102 and the outer contacts 104, 106 may be coplanar at the first main face 100A. The encapsulation body 102 and the outer contacts 104, 106 may be coplanar at the side faces 100C, 100D.

FIG. 1B shows a semiconductor package 100 which may be identical to the semiconductor package 10 of FIG. 1A, except that semiconductor package 100 comprises a first Ni layer 110 arranged on the outer contacts 104, 106 and a second Ni layer 120 arranged on the first Ni layer 110. The semiconductor package 100 may be configured to be mounted on a board such that the first main face 100A faces the board.

The first Ni layer 110 may be arranged directly on the outer contacts 104, 106 and the second Ni layer 120 may be arranged directly on the first Ni layer 110 and directly on the outer contacts 104, 106 as described below.

The semiconductor package 100 may comprise one or more further layers arranged on the second Ni layer 120, for example a protection layer. The one or more further layers may e.g. comprise an Au layer, an Ag layer, a Pd layer, or a Sn layer.

As shown in FIG. 1B, the first Ni layer 110 may be arranged solely on the first outer contact surfaces 104A, 106A (compare FIG. 1A), that is, solely on the first main face 100A of the semiconductor package 100. The second Ni layer 120 however may be arranged on the first outer contact surfaces 104A, 106A and also on the outer contact side faces 104C, 106D. That is, the second Ni layer may be arranged on the first main face 100A and on the side faces 100C, 100D of the semiconductor package 100.

At the first main face 100A of the semiconductor package 100 the second Ni layer 120 may be arranged directly on the first Ni layer 110 and at the side faces 100C, 100D of the semiconductor package 100 the second Ni layer 120 may be arranged directly on the respective outer contacts 104, 106.

The first Ni layer 110 may have been deposited by a Ni electroplating process and the second Ni layer 120 may have been deposited by an electroless Ni plating process. The first Ni layer 110 may be free of P and the second Ni layer 120 may comprise P as described further above.

The first Ni layer 110 may have a thickness measured along the direction of the arrow A in FIG. 1B of about or more than 0.1 μm, 0.2 μm, 0.5 μm, 0.8 μm, 1 μm, 2 μm, 3 μm, 4 μm, 5 μm, 6 μm, 8 μm, or 10 μm. The second Ni layer 120 may have a thickness measured along the direction of the arrow A of about or more than 0.1 μm, 0.2 μm, 0.5 μm, 0.8 μm, 1 μm, 2 μm, 3 μm, 4 μm, 5 μm, 6 μm, 8 μm, or 10 μm. The thickness of that particular part of the second Ni layer 120 that is arranged on the side faces 100C, 100D (measured along the arrow B in FIG. 1B) may be identical to the thickness of that part of the second Ni layer 120 that is arranged on the first main face 100A measured along arrow A.

According to an example of a semiconductor package 100, a combined thickness of the first and second Ni layers 110, 120 measured along the arrow A is about or more than 0.5 μm, 1 μm, 2 μm, 3 μm, 4 μm, 5 μm, 6 μm, 8 μm, or 10 μm.

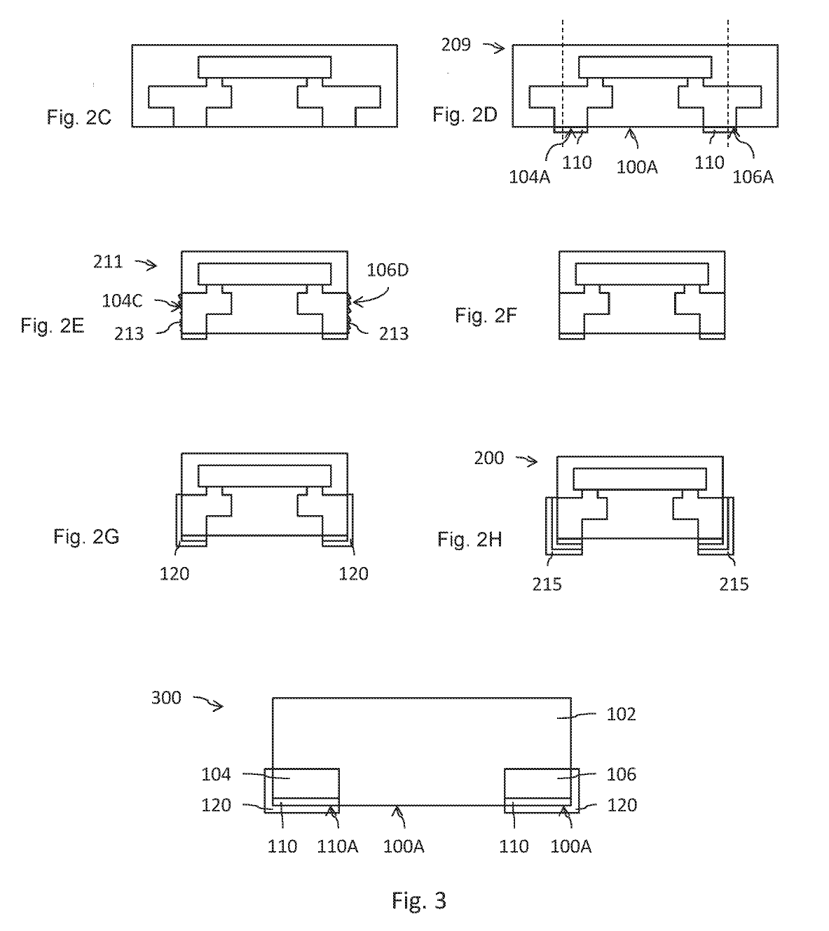

In the following with respect to FIGS. 2A to 2H a semiconductor package 200 is shown in various stages of fabrication. The semiconductor package 200 may be identical to the semiconductor package 100.

As shown in FIG. 2A, a substrate 201 is provided. The substrate 201 may comprise the outer contacts 104, 106 and may comprise or consist of a leadframe. The substrate 201 may be arranged on a temporary carrier 203. The temporary carrier 203 may comprise a foil or a tape, for example a thermo-release tape. A semiconductor chip 205 may be arranged on the substrate 201 and may be mechanically and/or electrically coupled to the substrate 201. The semiconductor chip 205 may in particular be mechanically and/or electrically coupled to the outer contacts 104, 106. The semiconductor chip 205 may e.g. be flip-chip bonded to the substrate 201.

As shown in FIG. 2B, the substrate 201 and the semiconductor chip 205 are encapsulated with an encapsulation material 207. For example, the substrate 201 and the semiconductor chip 205 are molded over with a mold compound.

As shown in FIG. 2C, the temporary carrier 203 may be removed, for example after the encapsulation material 207 has hardened.

As shown in FIG. 2D, the first Ni layer 110 may be formed on the first main face 100A, for example after removal of the temporary carrier 203. The first Ni layer 110 may be formed by Ni electroplating as described above.

According to an example, the outer contact surfaces 104A, 106A are completely covered by the first Ni layer 110. According to another example, the outer contact surfaces 104A, 106A are only partially covered by the first Ni layer 110. For example, about or more than 10%, 20%, 30%, 40%, 50%, or 60% of the outer contact surfaces 104A, 106A are covered by the first Ni layer 110.

Prior to the formation (e.g. by deposition) of the first Ni layer 110 a chemical deflash process (e.g. to remove any mold bleed out) and/or a cleaning process (e.g. cleaning by use of a waterjet) may be performed in order to prepare the outer contact surfaces 104A, 106A for the formation of the first Ni layer 110.

The intermediate product shown in FIG. 2D may be an artificial wafer 209 that comprises or consists of a multitude of semiconductor chips 205 and a multitude of substrates 201. According to an example, after formation of the first Ni layer 110 individual devices are singulated out of the artificial wafer 209. Device singulation may comprise cutting or sawing the artificial wafer, e.g. sawing along the dashed lines shown in FIG. 2D.

FIG. 2E shows a singulated device 211. The outer contact side faces 104C, 106D of the singulated device 211 may comprise burrs 213. The burrs 213 may stem from the sawing process.

As shown in FIG. 2F, the burrs 213 may be removed, e.g. by an etching process. An acidic or an alkaline etching chemical may be used. For example, the etching chemical may consist of or comprise ammonium chloride or sodium persulphate. The singulated device 211 may be dipped into a bath with the etching chemical. Alternatively or additionally to the chemical etching, the burrs 213 may be removed mechanically by a high pressure waterjet.

The presence of the first Ni layer 110 may significantly extend the time span that the singulated device 211 can be dipped into an etching bath without damaging the outer contacts 104, 106. For example, the time span may be extended by a factor of about 3.8.

After removal of the burrs 213, the outer contact side faces 104C, 106D may essentially comprise a surface roughness that is much smaller than the size of the burrs 213. This small surface roughness may be beneficial for the forming the second Ni layer 120 (see below) because the small surface roughness may improve the bonding between the outer contact side faces 104C, 106D and the second Ni layer 120.

As shown in FIG. 2G, the second Ni layer 120 is formed (e.g. deposited) on top of the first Ni layer 110 and the outer contacts 104, 106. Forming the second Ni layer 120 may comprise electroless Ni plating as described further above. The second Ni layer 120 may initially grow on top of the first Ni layer 110 and may subsequently extend (“creep up”) over the whole exposed surface area of the outer contacts 104, 106 (that is, over the first outer contact surfaces 104A, 106A and over the outer contact side faces 104C, 106D). For example, the second Ni layer 120 may creep up the outer contact side faces 104C, 106D. No catalyst like Pd may be necessary to initiate the electroless Ni plating process due to the presence of the first Ni layer 110.

As shown in FIG. 2H, the semiconductor package 200 may comprise a further layer 215 arranged on top of the second Ni layer 120. The further layer 215 may be a protective layer. The further layer 215 may be a metal or metal alloy layer and may e.g. comprise or consist of Au, Ag, Pd or Sn. The further layer 215 may be formed by an immersion process, e.g. an electroless Ni immersion gold (ENIG) process.

FIG. 3 shows a semiconductor package 300 that may be identical to the semiconductor packages 100 and 200 except that in semiconductor package 300 the first Ni layer 110 is partially encapsulated by the encapsulation body 102. In particular, as shown in FIG. 3, at the first main face 100A the encapsulation body 102 is coplanar with a first face 110A of the first Ni layer that faces away from the outer contacts 104, 106. The second Ni layer 120 is arranged on the first Ni layer 110 and on the outer contacts 104, 106 and may “stick out” of a circumference of the encapsulation body 102 as shown in FIG. 3.

The semiconductor package 300 may further comprise a semiconductor chip that is electrically and/or mechanically coupled to the outer contacts 104, 106. The semiconductor package 300 may further comprise a further metal layer arranged on the second Ni layer 120.

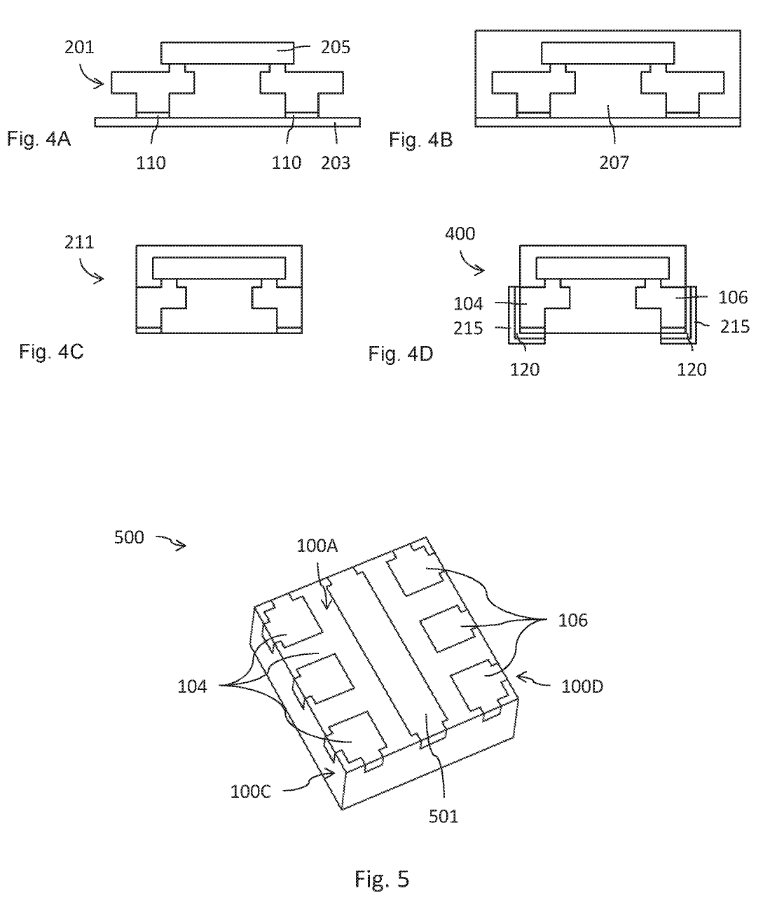

In the following with respect to FIGS. 4A to 4D a semiconductor package 400 is shown in various stages of fabrication. The semiconductor package 400 may be identical to the semiconductor package 300. Fabrication of the semiconductor package 400 may be identical to the fabrication of the semiconductor package 200 described with respect to FIG. 2A to 2H, except for the differences described below.

As shown in FIG. 4A, a substrate 201 arranged on a temporary carrier 203 is provided. A semiconductor chip 205 is coupled to the substrate 203. The first Ni layer 110 has been formed on the substrate 201 prior to attaching the substrate 201 to the temporary carrier 203. According to an example, a Ni electroplating process has been performed prior to attaching the substrate 201 to the temporary carrier 203. According to another example, the substrate 201 with the first Ni layer 110 already applied to it may be obtained from a supplier, e.g. a leadframe supplier.

As shown in FIG. 4B, encapsulation material 207 is applied over the semiconductor chip 205, the substrate 201 and the first Ni layer 110.

As shown in FIG. 4C, the temporary carrier 203 may be removed and a singulated device 211 may be fabricated, e.g. by sawing.

As shown in FIG. 4D, the semiconductor package 400 is fabricated by forming the second Ni layer 120 on top of the first Ni layer 110 and the outer contacts 104, 106.

According to an example, the semiconductor package 400 comprises the further metal layer 215 described with respect to FIG. 2H.

FIG. 5 shows a perspective view of a semiconductor package 500. The semiconductor package 500 may correspond to anyone of the semiconductor packages 100 to 400. The semiconductor package 500 comprises outer contacts 104 and 106 arranged on the first main face 100A along the side faces 100C, 100D, respectively. The semiconductor package 500 may comprise a further outer contact 501 arranged on the first main face 100A, e.g. arranged along a center line of the first main face 100A as shown in FIG. 5.

The outer contacts 104, 106 and 501 may comprise exposed outer contact side faces on the side faces of the semiconductor package 500 as shown in FIG. 5. The outer contacts 104, 106, 501 may all be covered by the first and second Ni layers as described with respect to the semiconductor packages 100 to 400.

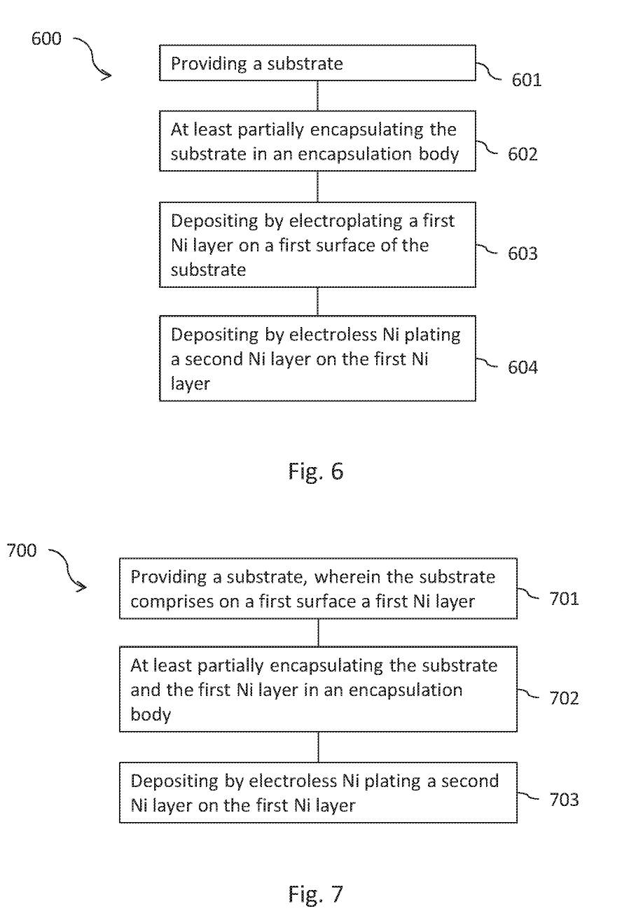

FIG. 6 shows a flow chart of a method 600 for fabricating a semiconductor package like the semiconductor packages 100 or 200. At 601 a substrate is provided. At 602 the substrate is at least partially encapsulated in an encapsulation body. At 603 a first Ni layer is deposited on a first surface of the substrate by electroplating. At 604 a second Ni layer is deposited on the first Ni layer by electroless Ni plating.

According to an example, the first Ni layer is deposited while the semiconductor package is part of an artificial wafer and the second Ni layer is deposited after singulation of the semiconductor package from the artificial wafer.

FIG. 7 shows a flow chart of a further method 700 for fabricating a semiconductor package like the semiconductor packages 300 or 400. At 701 a substrate is provided, wherein the substrate comprises on a first surface a first Ni layer. The first Ni layer may have been formed on the substrate by a Ni electroplating process. At 702 the substrate and the first Ni layer are at least partially encapsulated in an encapsulation body. At 703 a second Ni layer is deposited on the first Ni layer by electroless Ni plating.

According to an example, the first Ni layer is formed while the semiconductor package is part of an artificial wafer and the second Ni layer is deposited after singulation of the semiconductor package from the artificial wafer.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

What is claimed is:

1. A method for fabricating a semiconductor package, the method comprising:
providing a substrate;
at least partially encapsulating the substrate in an encapsulation body;
depositing by electroplating a first Ni layer on a first surface of the substrate; and
depositing by electroless Ni plating a second Ni layer on the first Ni layer.

2. The method of claim 1, wherein the first Ni layer is solely deposited on a first main face of the semiconductor package and wherein the second Ni layer is deposited on the first main face and on at least one side face of the semiconductor package.

3. The method of claim 1, wherein the depositing of the first Ni layer is performed while the semiconductor package is part of an artificial wafer and wherein the depositing of the second Ni layer is performed after singulation of the semiconductor package.

4. The method of claim 3, wherein depositing the first Ni layer comprises dipping as a whole the artificial wafer into an electrolyte solution.

5. The method of claim 3, wherein singulation comprises removing a burr from a Cu pad on at least one side face of the semiconductor package.

6. The method of claim 5, wherein the second Ni layer is directly deposited on the Cu pad on the at least one side face.

7. The method of claim 1, further comprising:
depositing a third layer on the first and second Ni layers, wherein the third layer comprises one or more of Au, Ag, Pd and Sn.

8. The method of claim 1, wherein the substrate comprises a leadframe.

9. A method for fabricating a semiconductor package, the method comprising:
providing a substrate, wherein the substrate comprises on a first surface a first Ni layer;
at least partially encapsulating the substrate and the first Ni layer in an encapsulation body; and
depositing by electroless Ni plating a second Ni layer on the first Ni layer.

10. The method of claim 9, wherein encapsulating the substrate comprises arranging the substrate on a temporary carrier such that the first Ni layer faces the temporary carrier and molding over the substrate and the temporary carrier.

11. The method of claim 9, wherein the first Ni layer is arranged on the substrate such that a first face of the first Ni layer faces away from the substrate, and wherein a first main face of the encapsulation body is coplanar with the first face of the first Ni layer.

12. The method of claim 9, wherein the first Ni layer has a thickness in the range of 0.2 μm to 10 μm.

13. The method of claim 9, further comprising:
singulating the semiconductor package from an artificial wafer prior to depositing the second Ni layer.

14. A semiconductor package, comprising:
an encapsulation body;
a substrate, the substrate being exposed from the encapsulation body on a first main face and at least one side face of the encapsulation body;
a first Ni layer arranged on the substrate at the first main face of the encapsulation body; and
a second Ni layer arranged on the first Ni layer and on the substrate at the at least one side face of the encapsulation body.

15. The semiconductor package of claim 14, wherein the second Ni layer comprises phosphorus and wherein the first Ni layer is free of phosphorus.

16. The semiconductor package of claim 15, wherein the phosphorus content of the first Ni layer is in the range of 5% to 12%.

17. The semiconductor package of claim 14, wherein the first Ni layer is a Ni electroplating layer and wherein the second Ni layer is a electroless Ni plating layer.

18. The semiconductor package of claim 14, wherein a combined thickness of the first Ni layer and the second Ni layer is in the range of 1 μm to 10 μm.

19. The semiconductor package of claim 14, wherein the semiconductor package is a leadless package.
